(19) United States
(12) Patent Application Publication
(10) Pub. No.: US 2019/0090352 A1
(43) Pub. Date: Mar. 21, 2019

(54) TRANSFER PRINT CIRCUITRY

(71) Applicant: VORBECK MATERIALS CORP., Jessup, MD (US)

(72) Inventors: DAN F SCHEFFER, FREDERICK, MD (US); KENNETH E FRITSCH, ARNOLD, MD (US); SRIRAM MANIVANNAN, BALTIMORE, MD (US)

(73) Assignee: VORBECK MATERIALS CORP., JESSUP, MD (US)

(21) Appl. No.: 15/527,698

(22) PCT Filed: Nov. 19, 2015
(86) PCT No.: PCT/US15/61490

§ 371 Date: Jul. 13, 2017

Related U.S. Application Data
(60) Provisional application No. 62/081,571, filed on Nov. 19, 2014.

(51) Int. Cl. H05K 3/02; H05K 1/09; H05K 3/12

(52) U.S. Cl. CPC H05K 3/022; H05K 1/092; H05K 2203/1545; H05K 2201/0323; H05K 3/1216

(57) ABSTRACT

In some embodiments, transfer print circuits and associated fabrication methods are provided. In some embodiments, some transfer print circuits include a graphene sheet-based conductive composition printed on at least a portion of a first layer. A second layer is in communication with at least a portion of the first layer in a manner that at least covers a portion of the graphene sheet-based conductive composition. An electrical device is in electronic communication with the graphene sheet-based conductive composition. The graphene sheet-based conductive composition includes graphene sheets having an interconnectivity and a horizontal alignment.

### CROSS-REFERENCE TO RELATED APPLICATIONS

This application is a 317 filing of International Application No. PCT/US15/61490 filed Nov. 19, 2015, which claims priority to U.S. Provisional Application No. 62/081,571 filed Nov. 19, 2014. These applications are each hereby incorporated herein by reference.

### BACKGROUND

The present invention relates generally to printed circuitry and specifically to transfer print circuitry. Current printed circuits typically utilize silver ink printed on polyester. Alternatively, printed circuits may comprise laminating thin copper strips in between two layers of polyethylene terephthalate (PET). These PET layers can then be coated with a thermosetting adhesive that activates during the lamination process.

### BRIEF DESCRIPTION OF THE DRAWINGS

FIG. 1 depicts fabrication steps, in accordance with an embodiment of the present invention.

FIG. 2 depicts additional fabrication steps, in accordance with an embodiment of the present invention.

FIG. 3 depicts additional fabrication steps, in accordance with an embodiment of the present invention.

FIG. 4 depicts additional fabrication steps, in accordance with an embodiment of the present invention.

FIG. 5 depicts additional fabrication steps, in accordance with an embodiment of the present invention.

FIG. 6 depicts fabrication steps, in accordance with an embodiment of the present invention.

FIG. 7 depicts additional fabrication steps, in accordance with an embodiment of the present invention.

FIG. 8 depicts additional fabrication steps, in accordance with an embodiment of the present invention.

### DETAILED DESCRIPTION

The descriptions of the various embodiments of the present invention are presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Printed circuitry allows for a wide variety of electronic, such as wearable and flexible electronics. Current printed circuits typically utilize silver ink printed on polyester. Alternatively, printed circuits may comprise laminating thin copper strips in between two layers of polyethylene terephthalate (PET). These PET layers can then be coated with a thermosetting adhesive that activates during the lamination process. Such printed circuits allow for dense packing of assembled electronic packages, three-dimensional packing, flexible electrical assemblies, lighter electrical connections, and dynamic electrical applications.

Embodiments of the present invention seek to provide a method of applying printed electronic circuitry on to substrate surfaces using transfer printing, wherein the transfer printing utilizes heat and/or pressure. Other aspects of the present invention seek to provide a method of applying printed electronic circuitry to unstable substrates (i.e. substrates that degrade upon exposure to a particular element within a plurality of seconds, minutes, hours, days, weeks, months, or years). Additional aspects of the present invention seek to provide articles having printed circuitry applied thereto utilizing heat transfer printing. Yet still other embodiments seek to provide electric circuitry that is dynamic, stretchable, flexible, and/or washable. Additional embodiments of the present invention seek to provide printed circuits that may be utilized in radio frequency identification (“RFID”) sensors, near field communication (“NFC”) sensors, antennas, heaters, touch pads, sensors, membrane switches, security devices, protected circuits, wearable circuitry, and wearable printed circuit boards.

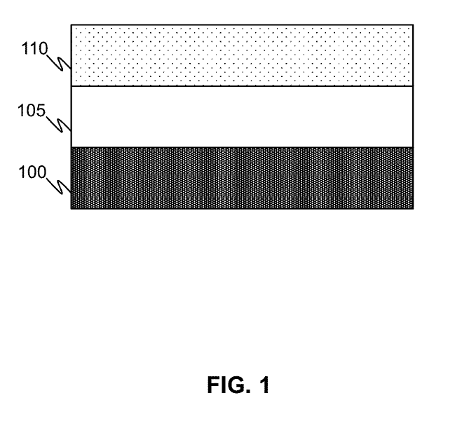

FIG. 1 depicts fabrication steps, in accordance with an embodiment of the present invention. Layer 105 can be applied to at least to a portion of the surface of substrate 100 using an applicable coating method. Applicable coating methods include, but are not limited to, chemical vapor deposition, physical vapor deposition, electrochemical deposition, spraying, roll-to-roll coating, printing, and spin coating. Substrate 100 can comprise polypropylene, polyethylene, PET, polyolefin, polyester, polystyrene, polyimide, super calendared kraft paper, clay coated kraft paper, machining coating kraft paper, and/or machine glazed paper. Substrate 100 can include woven and/or non-woven materials.

Layer 105 can be a release layer. Layer 105 can comprise silicone that is, for example, solvent-based, water-based, solvent less, heat curable, and/or UV curable. Layer 105 can comprise fluoropolymers, such as fluorosilicone, polytetrafluoroethylene (PTFE), perfluoroalkoxy (PFA), fluorinated ethylene propylene (FEP), ethylene tetrafluoroethylene (ETFE), polychlorotrifluoroethylene (PCTFE). Layer 110 can be deposited on at least a portion of layer 105. Layer 110 can be an electrically conducting layer. Layer 110 may include one or more inks, such as, graphene sheet-based inks, carbon-based inks (carbon nanotubes, carbon black, graphite, fullerenes), silver-based inks, insulating inks, and/or graphic inks. In certain embodiments, the graphene sheet-based conductive composition is prepared as disclosed in U.S. Pat. No. 8,278,757 to Crain et al., hereby incorporated herein by reference. Layer 110 may be deposited using any applicable coating methods (discussed above). Layer 110 can be deposited using screen printing. Layer 110 can be applied to surfaces using pressure and/or a predetermined temperature. The conductivity of layer 110 can increase as the application pressure and/or temperature increases. An increase in the application pressure of layer 110 can remove any air cavities that may be present. An increase in the application pressure of layer 110 can increase the horizontal alignment of the graphene sheets, which can increase graphene sheet interconnectivity. As graphene sheet interconnectivity increase, the conductivity of the conductive composition typically increases as a result. Layer 110 can be formed in a predetermined design, for example, circuit design and conductive lines. Although not depicted, layer 110 may comprise electrical devices, such as computer chips and memory chips.

Layer 110 can be cured using, for example, infrared heating, convection heating, and/or hot air. Layer 110 can be cured using a temperature range of about 80° C. to about 85° C., about 85° C. to about 90° C., about 90° C. to about 95° C., about 95° C. to about 100° C., about 100° C. to about 105° C., about 105° C. to about 110° C., about 110° C. to about 115° C., about 115° C. to about 120° C., about 120° C. to about 125° C., about 125° C. to about 130° C., about 130° C. to about 135° C., about 135° C. to about 140° C., about 140° C. to about 145° C., about 145° C. to about 150° C., about 150° C. to about 155° C., about 155° C. to about 160° C., about 160° C. to about 165° C., about 165° C. to about 170° C., about 170° C. to about 175° C., about 175° C. to about 180° C., as well as any value ranges included therein.

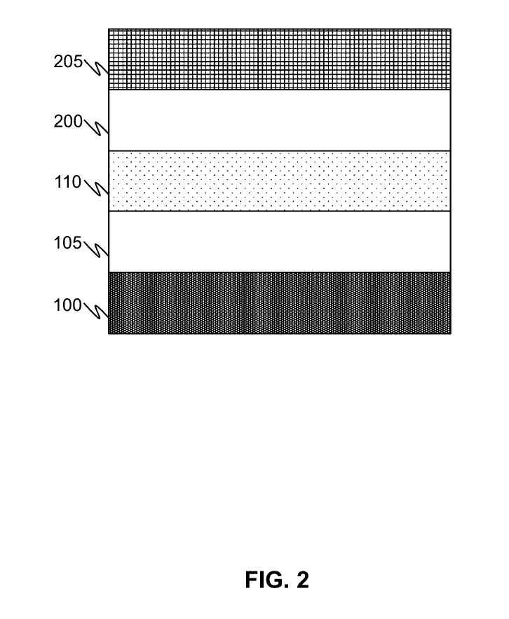

FIG. 2 depicts additional fabrication steps, in accordance with an embodiment of the present invention. Layer 200 can be deposited on to at least a portion of the surface of layer 110 and/or layer 105 (not shown) using an applicable application method (discussed above). Layer 200 can include bonding materials, including but not limited to, powder adhesives, printed adhesives/varnishes, and other applicable bonding materials. Applicable printed adhesives or varnishes can be solvent-based, water-based, or solvent-free. Applicable printed adhesives/varnishes can include polypropylene, polyethylene, polyolefin, polyester, polystyrene, polyvinylchloride, polyvinyl alcohol, and/or epoxy-based materials. Layer 200 can comprise pressure sensitive adhesives, such as a tape or label. Layer 200 can comprise a heat seal adhesive, which can include, but are not limited to, polyurethane, polyamide, polyester, and/or polyolefin-based materials.

Layer 200 can be applied on layer 110 using calendaring, heat pressing, or an applicable coating method. Layer 200 can be cured using an applicable curing temperature, such as about 60° C. to about 70° C., about 70° C. to about 80° C., about 80° C. to about 90° C., about 90° C. to about 100° C., about 100° C. to about 110° C., about 110° C. to about 120° C., about 120° C. to about 130° C., about 130° C. to about 140° C., about 140° C. to about 150° C., about 150° C. to about 160° C., 160° C. to about 170° C., about 170° C. to about 180° C., about 180° C. to about 190° C., about 190° C. to about 200° C., about 200° C. to about 210° C., about 210° C. to about 220° C., about 220° C. to about 230° C., about 230° C. to about 240° C., about 240° C. to about 250° C., as well as any value ranges included therein.

Applicable curing times include, but are not limited to, about 5 seconds to about 30 seconds, about 30 seconds to about 1 minute, about 1 minute to about 1.5 minutes, about 1.5 minutes to about 2 minutes, about 2 minutes to about 2.5 minutes, about 2.5 minutes to about 3 minutes, about 3 minutes to about 3.5 minutes, about 3.5 minutes to about 4 minutes, about 4 minutes to about 4.5 minutes, about 4.5 minutes to about 5 minutes, as well as any value ranges included therein. Layer 205 is applied to layer 200. Layer 205 can comprise fabrics and/or any applicable textile, which can include, but are not limited to, cotton, polyester fabric, nylon, silk, wool, and/or elastane-based fabrics.

Layer 200 can have a gauge of about 5 μm to about 10 μm, about 10 μm to about 15 μm, about 15 μm to about 20 μm, about 20 μm to about 25 μm, about 25 μm to about 50 μm, about 50 μm to about 75 μm, about 75 μm to about 100 μm, about 100 μm to about 125 μm, about 125 μm to about 150 μm, about 150 μm to about 175 μm, about 175 μm to about 200 μ, about 200 μm to about 225 μm, about 225 μm to about 250 μm, about 250 μm to about 275 μm, about 275 μm to about 300 μm, as well as any value ranges included therein. The applicable curing temperature can be lower or higher than the glass transition temperature (T_{g}) of layer 200. T_{g} reflects the temperature region wherein a material transitions from a hard, glassy-like state to a molten, soft, rubbery-like state.

Layer 205 can comprise composite materials, such as materials that include epoxy, unsaturated polyester, and/or carbon fibers. Layer 205 can comprise woven, non-woven, knits, and/or felt fabrics, including, but not limited to, acetate, acrylic, cotton, nylon, polyester, and wool. Layer 205 can comprise foams, including, but not limited to, polyethylene, polyurethane, and PVC-based foams. Layer 205 can comprise plastic materials, including, but not limited to, ABS, EVA, polycarbonate, polyethylene, polystyrene, polyurethane, Poron®, and PVC. Layer 205 can comprise metals, aluminum, epoxy, glass, fiberglass, leather, paper, rubber, Twintex®, steel, and wood. Layer 205 can comprise magnetic material, sheet rock, ceramics, silicone, Teflon®, Dyneema® and/or insulating materials.

Layer 205 can be applied to layer 200 using a pressure of about 0.25 bar to about 0.5 bar, about 0.5 bar to about 0.75 bar, about 0.75 bar to about 1.0 bar, about 1.0 bar to about 1.25 bar, about 1.25 bar to about 1.5 bar, about 1.5 bar to about 1.75 bar, about 1.75 bar to about 2.0 bar, about 2.0 bar to about 2.25 bar, about 2.25 bar to about 2.5 bar, about 2.5 bar to about 2.75 bar, about 2.75 bar to about 3.0 bar, about 3.0 bar to about 3.25 bar, about 3.25 bar to about 3.5 bar, about 3.5 bar to about 3.75 bar, about 3.75 bar to about 4.0 bar, about 4.0 bar to about 4.25 bar, about 4.25 bar to about 4.5 bar, about 4.5 bar to about 4.75 bar, about 4.75 bar to about 5.0 bar, about 5.0 bar to about 5.25 bar, about 5.25 bar to about 5.5 bar, about 5.5 bar to about 5.75 bar, about 5.75 bar to about 6.0 bar, about 6.0 bar to about 6.25 bar, about 6.25 bar to about 6.5 bar, about 6.5 bar to about 6.75 bar, about 6.75 bar to about 7.0 bar, as well as any value ranges included therein.

Layer 205 can be applied using a line speed of about 0.5 m/min to about 0.75 m/min, about 0.75 m/min to about 2.0 m/min, about 2.0 m/min to about 2.25 m/min, about 2.25 m/min to about 2.5 m/min, 2.5 m/min to about 2.75 m/min, about 2.75 m/min to about 3.0 m/min, about 3.0 m/min to about 3.25 m/min, about 3.25 m/min to about 3.5 m/min, 3.5 m/min to about 3.75 m/min, about 3.75 m/min to about 4.0 m/min, about 4.0 m/min to about 4.25 m/min, about 4.25 m/min to about 4.5 m/min, 4.5 m/min to about 4.75 m/min, about 4.75 m/min to about 5.0 m/min, about 5.0 m/min to about 5.25 m/min, about 5.25 m/min to about 5.5 m/min, 5.5 m/min to about 5.75 m/min, about 5.75 m/min to about 6.0 m/min, about 6.0 m/min to about 6.25 m/min, about 6.25 m/min to about 6.5 m/min, 6.5 m/min to about 6.75 m/min, about 6.75 m/min to about 7.0 m/min, about 7.0 m/min to about 7.25 m/min, about 7.25 m/min to about 7.5 m/min, about 7.5 m/min to about 7.75 m/min, about 7.75 m/min to about 8.0 m/min, about 8.0 m/min to about 8.25 m/min, about 8.25 m/min to about 8.5 m/min, about 8.5 m/min to about 8.75 m/min, about 8.75 m/min to about 9.0 m/min, about 9.0 m/min to about 9.25 m/min, about 9.25 m/min to about 9.5 m/min, about 9.5 m/min to about 9.75 m/min, about 9.75 m/min to about 10.0 m/min, as well as any value ranges included therein.

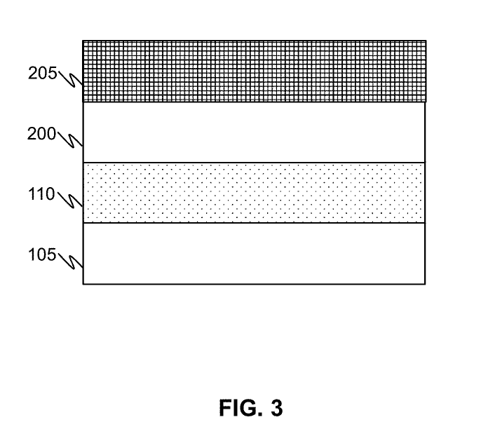

Heat and/or pressure can be applied to layer 205 and/or substrate 100. In an embodiment, heat is applied to layer 100 at about 150° C. for about 30 seconds at about 37 psi. In other embodiments, heat is applied to layer 100 at about 190° C. for about 60-90 seconds at about 85 psi. FIG. 3 depicts additional fabrication steps, in accordance with an embodiment of the present invention. Here, layer 100 may be removed from layer 105 following the application of layer 205 to layer 200 while layer 100 is above room temperature. Layer 100 may be removed from layer 105 subsequent to layer 100 returning to about room temperature. Although not shown, layers 100 and 105 may be removed from layer 110.

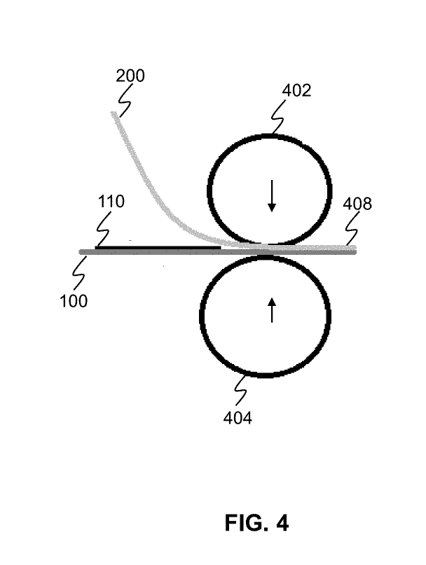

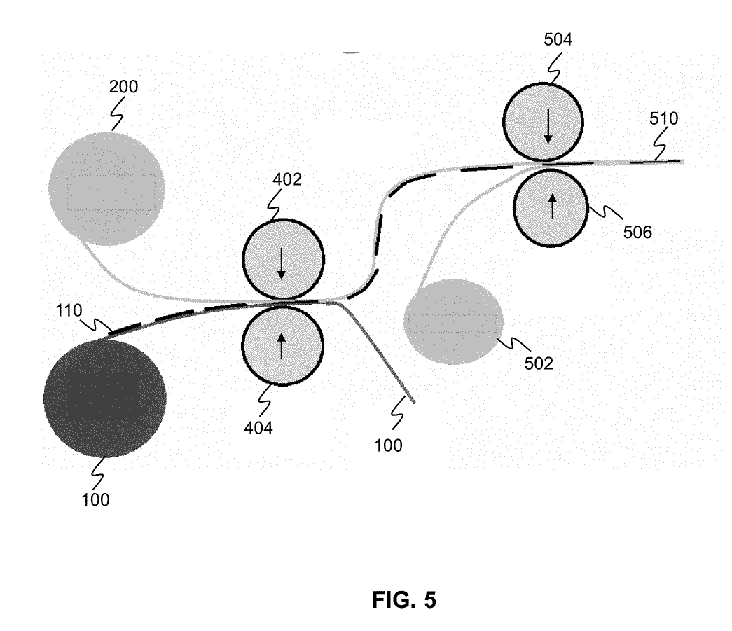

FIG. 4 depicts fabrication steps, in accordance with an embodiment of the present invention. Specifically, FIG. 4 illustrates a roll-based fabrication technique that can form transfer print circuitry. Rollers 402 and 404 are rollers that are capable of applying pressure and/or heat to layers 100, 110, and 200 in the proximate direction depicted by the arrows. Layer 110 may be applied on layer 100 via layer 105 (not depicted) as described above in reference to FIG. 1. Layers 100 and 110 may be applied on layer 200 via pressure and/or heat via rollers 402 and 404, thereby forming final product. Finished product 408 can undergo additional processing, such as sizing and/or adherence to one or more additional structures or materials. Finished product 408 can also under additional processing such as that depicted in FIG. 5 (discussed above).

FIG. 5 depicts additional fabrication steps, in accordance with an embodiment of the present invention. Specifically, FIG. 5 illustrates a roll-based fabrication techniques that may proceed subsequent to the fabrication steps of FIG. 4. Here, layer 110 can be transferred to layer 200 utilizing pressure and/or heat via rollers 402 and/or 404. Subsequent to the transfer, layer 100 can be recycled for future usage. Layer 502 can be applied to at least a portion of layers 200 and 110 via rollers 504 and 506 using heat and pressure. Layers 502 and 200 can include similar material. Final product 510 can undergo additional processes, such as sizing and/or adherence to additional materials.

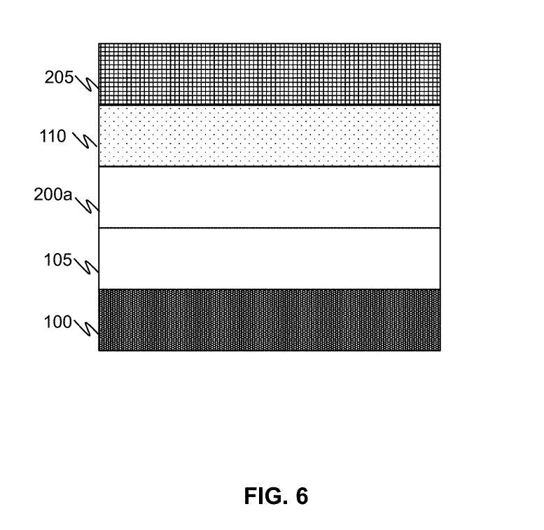

FIGS. 6-8 illustrate fabrication steps that may utilize previously discussed layers, materials, and/or techniques. FIG. 6 depicts fabrication steps, in accordance with an embodiment of the present invention. Layer 105 can be formed on at least a portion of layer 100 as discussed above. Layer 200a can be formed on at least a portion layer 105 in a similar manner utilized to form layer 200 on at least a portion of layers 110 and/or 105 (discussed above). Layer 200a can include an adhesive. Layers 200a and 200 can include similar materials. Layer 110 can be formed on at least a portion of layer 200a in a similar manner utilized to form layer 110 on at least a portion of layer 105. Layer 205 can be formed to at least a portion of layers 110 and/or 200a in a similar manner to form layer 205 to at least a portion of layers 200 and/or 110. Layer 205 can be a substrate layer.

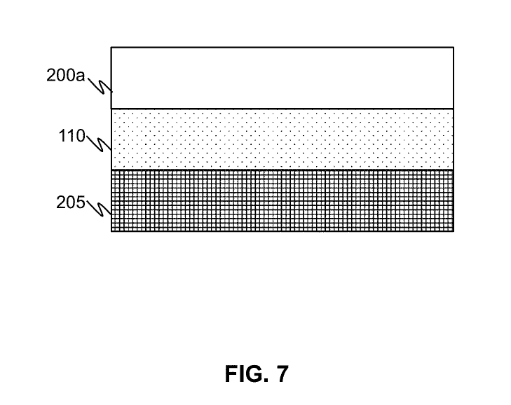

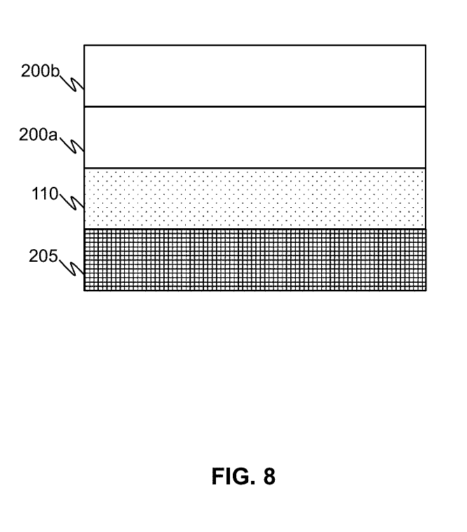

FIG. 7 depict additional fabrication steps, in accordance with an embodiment of the present invention. At least a portion of layers 105 can be separated from layer 200a utilizing in a similar manner utilized to separate layers 110 and 200 (discussed above). FIG. 8 depicts additional fabrication steps, in accordance with an embodiment of the present invention. Layer 200b can be formed on at least a portion of layer 200a in a similar manner that is used to form layer 200a on layer 110. Layers 200b and 200 can include similar materials. The final product depicted in FIG. 8 can undergo additional processing (as discussed above).

The above description is intended to be illustrative, and not restrictive. For example, the above-described embodiments and examples can be used in combination with each other. Other embodiments can be used, such as by one of ordinary skill in the art upon reviewing the above description. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

In the appended claim the terms “first,” “second,” and “third,” etc. are used merely as labels, and are not intended to impose numerical requirements on their objects. The abstract is provided to comply with 37 C.F.R. § 1.72(b), to allow the reader to quickly ascertain the nature of the technical disclosure. It is submitted with the understanding that it will not be used to interpret or limit the scope of meaning of the claims.

What is claimed is:

1. A method for fabricating a transfer print circuit, the method comprising:
applying a conductive composition to at least a portion of a first side of a first layer;
applying a second layer to at least a portion of the first side of the first layer in a manner that at least partially covers the conductive composition;
wherein the conductive composition comprises graphene sheets;
wherein the first layer is a release layer, a substrate, or an adhesive layer; and
wherein the second layer is a release layer, a substrate, or an adhesive layer.

2. The method of claim 1, wherein the step of applying the conductive composition includes utilizes a printing method.

3. The method of claim 1, further comprising positioning a computing device in electronic communication with the conductive composition.

4. The method of claim 1, wherein the conductive composition further comprises carbon nanotubes, graphite, fullerenes, carbon black, silver, gold, copper, and/or a conductive material.

5. The method of claim 1, wherein the substrate includes a metal material, a composite material, a fabric material, a plastic material, a rubber material, a cellulose material, a leather material, a glass, Teflon, Spandex, a foam, and/or a wood material.

6. The method of claim 1, wherein the step applying a conductive composition comprises applying pressure and/or heat to the conductive composition.

7. The method of claim 1, wherein the adhesive layer comprises a powder adhesive, a varnish, a solvent based adhesive, water based adhesive, a solvent free adhesive, a pressure sensitive adhesive, and/or a heat seal adhesive.

8. The method of claim 6, wherein an increase in the pressure and/or temperature increases the conductivity of the conductive composition.

9. The method of claim 1, wherein an increase in the pressure and/or temperature increases horizontal alignment of the graphene sheets and/or interconnectivity of the graphene sheets.

10. An article comprising at least one transfer print circuit of claim 1.

11. A printed circuit comprising:
a conductive composition positioned on at least a portion of a first layer;
a second layer in communication with at least a portion of the first layer in a manner that at least covers a portion the conductive composition;
wherein the conductive composition comprises graphene sheets;
wherein the first layer is a release layer, a substrate, or an adhesive layer; and
wherein the second layer is a release layer, a substrate, or an adhesive layer.

12. The printed circuit of claim 11, wherein the conductive composition is formed using a printing method.

13. The printed circuit of claim 11, further comprising an computing device in electronic communication with the conductive composition.

14. The printed circuit of claim 11, wherein the conductive composition further comprises carbon nanotube, graphite, fullerenes, silver, gold, copper, and/or a conductive material.

15. The printed circuit of claim 10, wherein the substrate includes a metal material, a composite material, a fabric material, a plastic material, a rubber material, a cellulose material, a leather material, a glass, Teflon, Spandex, a foam, silicon, polyethylene, and/or a wood material.

16. The printed circuit of claim 10, wherein the adhesive layer comprises a powder adhesive, a varnish, a solvent based adhesive, water based adhesive, a solvent free adhesive, a pressure sensitive adhesive, a heat seal adhesive, a powder adhesive, a varnish, polypropylene, polyethylene, polyolefin, polyester, polystyrene, polyvinylchloride, polyvinyl alcohol, and/or epoxy.

17. The printed circuit of claim 10, wherein the conductive composition is applied using an application pressure and/or an application temperature.

18. The printed circuit of claim 17, wherein an increase in the application pressure and/or the application temperature increases the conductivity of the conductive composition.

19. The printed circuit of claim 10, wherein the release liner includes a silicone that is solvent-based, water-based, solvent-less, heat curable, or UV curable; and/or comprises a silicone fluoropolymers that includes fluorosilicone, polytetrafluoroethylene, perfluoroalkoxy, fluorinated ethylene propylene, ethylene tetrafluoroethylene, and/or polychlorotrifluoroethylene.

20. The printed circuit of claim 17, wherein an increase in the application pressure and/or the application temperature increases horizontal alignment of the graphene sheets and/or interconnectivity of the graphene sheets.
